(19) United States
(12) Patent Application Publication
(10) Pub. No.: US 2015/0325414 A1
(43) Pub. Date: Nov. 12, 2015

(54) UNITIZED CONFINEMENT RING ARRANGEMENTS AND METHODS THEREOF

(71) Applicant: Lam Research Corporation, Fremont, CA (US)

(72) Inventors: Rajinder Dhindsa, San Jose, CA (US); Rajaramanan Kalyanaraman, Fremont, CA (US); Sathyanarayanan Mani, Fremont, CA (US); Gautam Bhattacharyya, Fremont, CA (US)

(21) Appl. No.: 14/802,972

(22) Filed: Jul. 17, 2015

Related U.S. Application Data
(62) Division of application No. 12/890,990, filed on Sep. 27, 2010.
(60) Provisional application No. 61/246,526, filed on Sep. 28, 2009.

(51) Int. Cl. H01J 37/32

(52) U.S. Cl. CPC H01J 37/32449; H01J 37/32532; H01J 37/32816; H01J 2237/334

(57) ABSTRACT

An arrangement for performing pressure control in a plasma processing chamber comprising an upper electrode, a lower electrode, a unitized confinement ring arrangement wherein the upper electrode, the lower electrode and the unitized confinement ring arrangement are configured at least for surrounding a confined chamber region to facilitate plasma generation and confinement therein. The arrangement further includes at least one plunger configured for moving the unitized confinement ring arrangement in a vertical direction to adjust at least one of a first gas conductance path and a second gas conductance path to perform the pressure control, wherein the first gas conductance path is formed between the upper electrode and the unitized confinement ring arrangement and the second gas conductance path is formed between the lower electrode and the single unitized ring arrangement.

### CROSS REFERENCE TO RELATED APPLICATION

This application is a divisional of and claims priority under 35 U.S.C. §120 to U.S. patent application Ser. No. 12/890,990, filed Sep. 27, 2010, entitled “UNITIZED CONFINEMENT RING ARRANGEMENTS AND METHODS THEREOF”, which claims priority under 35 USC. 119(e) to U.S. Provisional Patent Application No. 61/246,526, filed on Sep. 28, 2009 all of which are incorporated herein by reference in their entirety for all purposes.

### BACKGROUND OF THE INVENTION

Advances in plasma processing have provided for growth in the semiconductor industry. In today's competitive market, the ability of a manufacturing company to be able to minimize waste and produce high quality semiconductor devices gives the manufacturing company a competitive edge. Accordingly, tight control of the process parameters is generally needed to achieve satisfactory results during substrate processing. Thus, manufacturing companies have dedicated time and resources to identify methods and/or arrangements for improving substrate processing.

In a plasma processing system, such as a capacitively-coupled plasma (CCP) or an inductively-coupled plasma (ICP) processing system, the manufacturing of semiconductor devices may require multi-step processes employing plasma within a processing chamber. During processing, gas may interact with radio frequency (RF) power to form plasma. Confinement rings may be employed to control plasma formation and to protect the process chamber walls. The confinement rings may include multiple rings stacked on top of one another and are configured to surround the periphery of the chamber volume in which plasma is to form (i.e., confined chamber region).

The confinement rings may also be employed to control the pressure level within the confined chamber region. Typically, during processing, the processing chamber is usually maintained at a predefined pressure for each process step in order to generate the desired plasma needed for processing the substrate. Those skilled in the arts are aware that a stable plasma is important during substrate processing. Thus, the ability to maintain tight control of the process parameters during substrate processing is essential for plasma stability. When the process parameters (e.g., pressure or other parameters) are outside of a narrow, pre-defined window, the process parameters may have to be adjusted to maintain a stable plasma in accordance with the required processing recipe.

FIG. 1 shows a simple cross-sectional diagram of a confinement ring arrangement within a processing chamber. Consider the situation wherein, for example, a substrate 102 is disposed on top of a lower electrode 104 (such as an electrostatic chuck). During substrate processing, plasma 106 may form between substrate 102 and upper electrode 108. Surrounding the plasma is a plurality of confinement rings (110a, 110b, 110c, 110d, etc.), which may be employed to confine plasma 106 and to control the pressure within the confinement region (such as a confined chamber region 118). The gaps (such as gaps 112a, 112b, 112c, etc.) between the plurality of confinement rings may be adjusted to control the exhaust rate, hence the pressure above the substrate surface.

In a typical processing chamber that employs the plurality of confinement rings (110a, 110b, 110c, 110d, etc.), the confinement rings may have attachment points. Positioned at each attachment point is a plunger (such as 114 and 116, for example). To control the volume of pressure within confinement region 118, a plunger controller module 120 (such as a CAM ring arrangement) may move the plungers vertically (up/down) to adjust the gaps between the plurality of confinement rings (110a, 110b, 110c, 110d, etc.). By adjusting the gaps between the confinement rings, the conductance rate of gas being exhausted from the confined chamber region may be controlled, thereby controlling the amount of pressure within the processing chamber. In other words during substrate processing, if the chamber pressure is outside of the designated range (such as that determined by the current recipe step), the confinement rings may be adjusted. In an example, to increase the pressure within the processing chamber, the gaps between the confinement rings may be reduced.

In a competitive market, the ability to simplify a process and/or components usually gives the manufacturing company a competitive edge over its competitors. In view of the increasingly competitive substrate processing market, a simple arrangement that provides for pressure control while confining plasma formation within the plasma generating region is desirable.

### SUMMARY OF THE INVENTION

The invention relates, in an embodiment, to an arrangement for performing pressure control in a plasma processing chamber comprising an upper electrode, a lower electrode, a unitized confinement ring arrangement wherein the upper electrode, the lower electrode and the unitized confinement ring arrangement are configured at least for surrounding a confined chamber region to facilitate plasma generation and confinement therein. The arrangement further includes at least one plunger configured for moving the unitized confinement ring arrangement in a vertical direction to adjust at least one of a first gas conductance path and a second gas conductance path to perform the pressure control, wherein the first gas conductance path is formed between the upper electrode and the unitized confinement ring arrangement and the second gas conductance path is formed between the lower electrode and the single unitized ring arrangement.

These and other features of the present invention will be described in more detail below in the detailed description of the invention and in conjunction with the following figures.

### BRIEF DESCRIPTION OF THE SEVERAL VIEWS OF THE DRAWINGS

The present invention is illustrated by way of example, and not by way of limitation, in the figures of the accompanying drawings and in which like reference numerals refer to similar elements and in which:

FIG. 1 shows a simple cross-sectional diagram of a confinement ring arrangement within a processing chamber.

FIGS. 2-5 show, in embodiments of the invention, cross-sectional views of different configurations of a single unitized confinement ring arrangement for performing pressure control and plasma confinement.

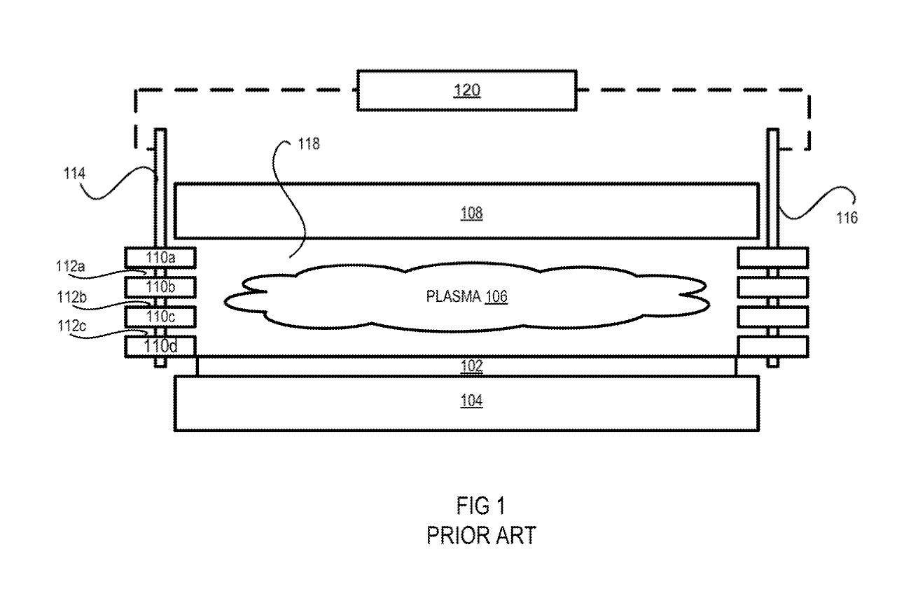

### DETAILED DESCRIPTION OF EMBODIMENTS

The present invention will now be described in detail with reference to a few embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

Various embodiments are described hereinbelow, including methods and techniques. It should be kept in mind that the invention might also cover articles of manufacture that includes a computer readable medium on which computer-readable instructions for carrying out embodiments of the inventive technique are stored. The computer readable medium may include, for example, semiconductor, magnetic, opto-magnetic, optical, or other forms of computer readable medium for storing computer readable code. Further, the invention may also cover apparatuses for practicing embodiments of the invention. Such apparatus may include circuits, dedicated and/or programmable, to carry out tasks pertaining to embodiments of the invention. Examples of such apparatus include a general-purpose computer and/or a dedicated computing device when appropriately programmed and may include a combination of a computer/computing device and dedicated/programmable circuits adapted for the various tasks pertaining to embodiments of the invention.

In accordance with embodiments of the present invention, a single or unitized (the terms are synonymous in the context of the present invention) confinement ring arrangement is provided for confining plasma and for controlling pressure within a plasma generating region. As the term is defined herein, a unitized confinement ring is a ring which may be formed of a single block of material, in one or more embodiments, or may comprise of multiple individually manufactured parts that are later assembled, in other embodiments. When the multiple parts are assembled to form the single unitized confinement ring, the various parts of the confinement are nonmovable relative to one another during deployment and retraction. This is unlike the prior art situation when the rings may expand and collapse during deployment and retraction. In an embodiment, the unitized ring may include one or more rings.

Embodiments of the invention include a unitized confinement ring arrangement that may be implemented with different configurations, depending upon the requirement of the processing chamber. Embodiments of the invention also include an automatic feedback arrangement for monitoring and stabilizing the pressure within the plasma generating region.

In an embodiment, a unitized confinement ring arrangement is provided for confining plasma and controlling the pressure within the plasma generating region. The confinement ring may surround the periphery of the processing chamber area in which plasma is to form (i.e., confined chamber region) to prevent plasma from escaping the confined chamber region and to protect the chamber wall. Generally, one or more paths (channels) are provided for exhausting gas (such as neutral gas species) from the confined chamber region. Since conductance rate of gas exhaust within the confined chamber region is usually a factor of the size and length of the path available for exhausting the gas from the plasma generating region, different arrangements may be provided for implementing a unitized confinement ring within the processing chamber, in an embodiment.

In one embodiment, by moving the confinement ring vertically up/down, the size of the path may be reduced or expanded to change the conductance rate, thereby modifying the pressure within the confined chamber region. In an example, by moving the confinement ring downward, the gap between the bottom surface of the unitized confinement ring and the top surface of the bottom ground extension may be reduced. Thus, less gas may be exhausted from the confined chamber region, thereby increasing the pressure level within the plasma generating region.

In another embodiment, the length of the path may also be adjusted when the confinement ring is moved vertically up/down. In an example, moving the confinement ring upward may cause the path between the left side wall of the confinement ring and the right side wall of the upper electrode to lengthen. A longer path usually creates more resistance to the gas flow. Thus, less gas is exhausted and the pressure within the confined chamber region is increased.

Besides the size and length of the path, the number of paths available may also impact the overall conductance rate for exhausting gas from the confined chamber region. In an example, if two possible paths exist for exhausting gas from the confined chamber region, both paths may be considered in determining the overall conductance rate. This is especially true if one path provides a counter effect on the conductance rate of the other path. For example, an upper path and a lower path are available for exhausting gas from the confined chamber region. When the confinement ring is moved downward, the upper path is shortened (therefore reducing resistance to flow) while the lower path is reduced (thereby increasing resistance to flow). To calculate the overall conductance rate for the confined chamber region, the conductance rates for both of the upper path and the lower path may be considered.

In an embodiment, one or more slots may be created in the unitized confinement ring to facilitate exhaust flow. The slots may be equal in length or may have different lengths. The slots may be equally or unequally spaced. The length and cross-sectional area of the slots may also vary.

In an embodiment, a feedback arrangement may be provided for confining pressure and managing pressure control. The feedback arrangement may include a sensor configured for monitoring the pressure level within the confined chamber region. The data collected by the sensor is sent to a precision vertical movement arrangement for analysis. A comparison to a predefined threshold range may be performed. If the pressure level is outside of the threshold range, the confinement ring may be moved into a new position to change the pressure level locally within the confined chamber region.

The features and advantages of the present invention may be better understood with reference to the figures and discussions that follow.

Equation 1 below shows a simple equation illustrating the conductance of controllable gap.

Conductance of controllable gap˜(C*Dⁿ)/L [Equation 1]

C=constant (function of gas molecular weight, temperature, etc.)

D=the width of the channel for evacuating the exhaust gas

L=length of the channel for evacuating the exhaust gas

n=number of channels (such as slots) for evacuating the exhaust gas

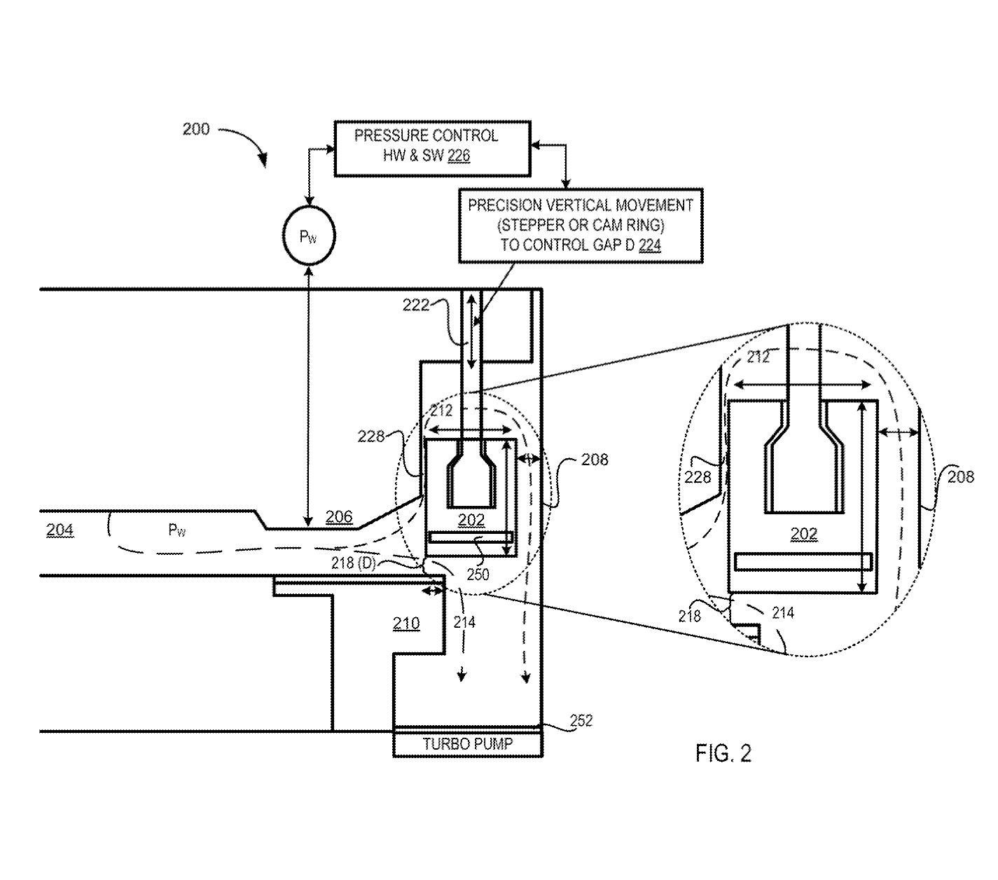

As shown by Equation 1, the conductance rate of gas exhaust may be controlled by varying one of the variables (D, L, or n) above. The next few figures (FIG. 2-FIG. 5) provides examples of different configurations for implementing a single unitized confinement ring in controlling at least one of plasma confinement and pressure control within a confined chamber region.

FIG. 2 shows, in an embodiment of the invention, a simple diagram of a partial view of a processing chamber 200 with a unitized confinement ring arrangement for performing pressure control and/or plasma confinement. In an embodiment, processing chamber 200 may be a capacitively-coupled plasma processing chamber.

In this document, various implementations may be discussed using a capacitively-coupled plasma (CCP) processing system as an example. This invention, however, is not limited to a CCP processing system and may include other processing system, such as an inductively-coupled plasma (ICP) processing system, that may exist. Instead, the discussions are meant as examples and the invention is not limited by the examples presented.

During substrate processing, a plasma, which may be employed to etch a substrate, may form within a confined chamber region 204. In order to control plasma formation and to protect the processing chamber parts, a unitized confinement ring 202 may be employed to surround the periphery of confined chamber region 204, in an embodiment. In an embodiment, at least a portion of confinement ring 202 is generally cylindrical in shape and is positioned between an upper electrode 206 and a chamber wall 208. In addition, a part of the width of confinement ring 202 is overlapping a bottom ground extension 210. Confinement ring 202 may be made from a dielectric material or an RF ground conductive material, in an embodiment. In addition to the unitized confinement ring, the periphery of confined chamber region 204 may also be defined by an upper electrode 206, the substrate disposed on the lower electrode, a bottom ground extension 210 and other chamber structures.

During substrate processing, gas may flow from a gas distribution system (not shown) into confined chamber region 204 to interact with RF power to create plasma. In order to evacuate exhaust gas from the confinement region (confined chamber region 204), one or more exhaust paths are usually provided. In an example, the exhaust gas may be evacuated from confined chamber region 204 by flowing either along an upper path 212 or a lower path 214. In an embodiment, the exhaust gas evacuation rate from confined chamber region 204 may be controlled by moving confinement ring 202 vertically (up/down).

As shown by Equation 1 above, the conductance rate of gas exhaust may be controlled by varying one of the variables (D, L, or n). In an example, by moving confinement ring 202 vertically up/down, a gap 218 (D), which is the distance between the bottom surface of confinement ring 202 and the top surface of bottom ground extension 210 may be adjusted. In other words, by adjusting gap 218, the rate of conductance may vary, thereby changing the pressure level (P_{w}) within confined chamber region 204. For example, by reducing gap 218, less gas is exhausted from confined chamber region 204, thereby increasing the pressure level (P_{w}) within confined chamber region 204. Conversely, by increasing gap 218, more gas may be exhausted from confined area 204, thereby decreasing the pressure level (P_{w}) within confined chamber region 204.

Since two paths (214 and 212) are shown in FIG. 2 for exhausting gas from confined chamber region 204, the overall conductance rate for confined chamber region 204 may be a factor of both the lower path conductance rate and the upper path conductance rate. Similar to lower path 214, when confinement ring 202 is adjusted, the upper path conductance rate may also change. In an embodiment, the counter effect may vary depending upon the length of the path (L). In an example, by moving confinement ring 202 downward, the portion of upper path 212 between unitized confinement ring 202 and upper electrode 206 is shortened (i.e., the length of the upper path 212), thereby increasing the rate of exhaust. In another example, the rate of exhaust may decrease as the portion of upper path 212 between unitized confinement ring 202 and upper electrode 206 is lengthened when confinement ring 202 is moved vertically upward since a longer path usually creates more resistance to the gas flow.

In another embodiment, the distance (gap 228) between the side wall of confinement ring 202 and the right side wall of upper electrode 206 may have an impact on the overall conductance rate. In other words, the width of gap 228 may change the conductance rate of upper path 212. In an example, a wider gap 228 may increase the conductance rate of upper path 212. For example, a processing chamber A with a narrow gap 228 may have less impact on the overall conductance rate than a processing chamber B with a wider gap 228.

In an embodiment, a set of plungers 222 may be attached to confinement ring 202 at available attachment points. The number of plungers may depend upon the number of attachment points. The plungers may be moved concurrently to adjust confinement ring 202 vertically up/down. In an embodiment, set of plungers 222 may be coupled to a precision vertical movement arrangement 224 (such as a stepper assembly, a CAM ring arrangement, etc.). Precision vertical movement arrangement 224 may be employed to move confinement ring 202 into a position that enables the pressure level (P_{w}) within confined chamber region 204 to be maintained at the desired recipe step level.

In an embodiment, set of plungers 222 may be moved in response to processing data (such as pressure data) collected by a set of sensors (such as sensor 226). The pressure data may be sent to precision vertical movement arrangement 224, which may also include a module for processing and analyzing the pressure data. If the processing data traverses a threshold range, set of plungers 222 may be moved vertically up/down in order to change the pressure level within confined chamber region 204. In an example, if the processing data indicates that the pressure level is above the pre-defined threshold, gap 218 may be increased to reduce the pressure within confined chamber region 204. In an embodiment, at least one of the collection of data, the analysis of data and the adjustment of set of plungers 222 may be performed automatically without human intervention.

As discussed herein, the term traverse may include exceed, fall bellow, be within range, and the like. The meaning of the word traverse may depend upon the requirement of the threshold value/range. In an example, if the recipe requires the pressure value, for example, to be at least a certain value, then the processing data is considered to have traversed the threshold value/range if the pressure value is below the threshold value/range. In another example, if the recipe requires the pressure value, for example, to be below a value, then the processing data has traversed the threshold value/range if the pressure value is above the threshold value/range.

In an embodiment, confinement ring 202 may include one or more slots 250. The set of slots (n) may be employed to provide for additional paths for exhausting gas from the confined chamber region, in an embodiment. The slots may be equal in length or may have different lengths. The slots may be equally or unequally spaced. The length and cross-sectional area of the slots may also vary. In one embodiment, the set of slots may include a path to facilitate detection of plasma condition by an optical sensor, which may be employed to capture end point data during substrate processing.

In an embodiment, confinement ring 202 may be employed to manage plasma confinement while an external component may be employed to perform pressure control. Those skilled in the art are aware that some recipes may require the components within a processing chamber to be stationary during processing. In this type of environment, confinement ring 202 may be positioned at a predetermined stationary position. The predetermined stationary position may be at a position that minimizes the possibility of plasma unconfinement. In an embodiment a valve such as a vat valve 252 may be employed to adjust the pressure level within confined chamber region 204.

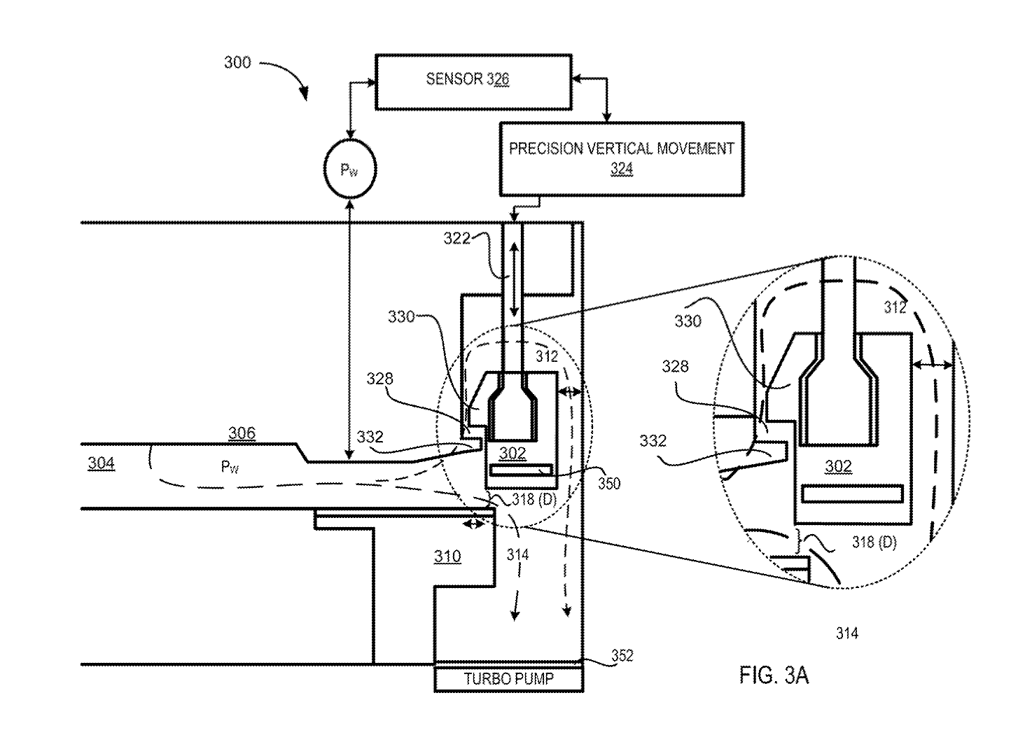

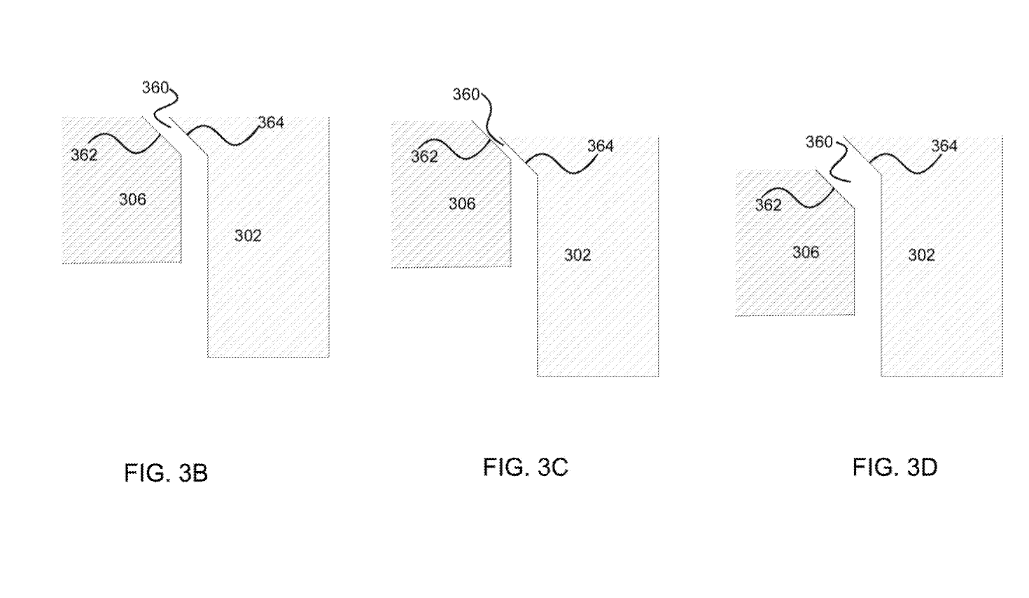

FIG. 3A shows, in an embodiment of the invention, a cross-sectional view of a unitized confinement ring with a high inductance upper path implementation. In an embodiment the plasma processing system may be a capacitively-coupled plasma (CCP) processing system. Processing chamber 300 may include a confinement ring 302 configured to surround the periphery of the chamber volume where plasma is formed (i.e., confined chamber region 304). Confinement ring 302 is similar to confinement ring 202 except that the upper part of confinement ring 302 has a shoulder feature 330.

Similar to FIG. 2, an upper electrode 306 and a bottom ground extension 310 may also defined part of the periphery of confined chamber region 304. In an embodiment, upper electrode 306 may include a protrusion (a shelf feature 332). Thus, when confinement ring 302 is moving vertically downward, the distance that confinement ring 302 may travel may not only be defined by the top surface of bottom ground extension 310 (similar to FIG. 2) but also by shelf feature 332.

During substrate processing, two paths (312 and 314) may be available for evacuating the exhaust gas from a confined chamber region 304. The conductance rate may be controlled by adjusting a gap 318 (D) between the bottom surface of confinement ring 302 and the top surface of bottom ground extension 310. In an example, to reduce the conductance rate, a set of plungers 322 may be lowered to cause confinement ring 302 to travel vertically downward thereby narrowing gap 318. At the same time, a gap 328 is also narrowed as shoulder feature 330 get closer in proximity to shelf feature 332 of upper electrode 306.

In an embodiment, gap 318 and gap 328 may have the same width. Thus, when shoulder feature 330 is resting on shelf feature 332, gas is not being exhausted from confined chamber region 304 since both paths 312 and 314 have been choked off.

In another embodiment, gaps 318 and 328 may have different width measurements. In an example, gap 318 may be larger than gap 328. In this example, only path 312 is choked off when shoulder feature 330 rests on shelf feature 332 while path 314 is still available for evacuating the exhaust gas. In another example, gap 318 is smaller than gap 328. As a result, only path 314 is choked off when the bottom surface of confinement ring 302 rests on the top surface of bottom ground extension 310. In other words, path 312 is still available for evacuating the exhaust gas.

In an embodiment, instead of a shelf-shoulder arrangement, an upper left side wall (364) of confinement ring 302 may be sloped (as shown in FIG. 3B, FIG. 3C, and FIG. 3D). In an example, upper left side wall 364 of confinement ring 302 may be at an angle less than 90 degrees. Similarly, a portion of the right side wall (362) of upper electrode 306 may be sloped. In an example, a portion of right side wall 362) of upper electrode may be at an angle greater than 90 degrees. Thus, a gap 360 may be formed between the two side walls to enable the exhaust gas to be evacuated. The conductance rate may be controlled by adjusting gap 360. In an example, to reduce the conductance rate, confinement ring 302 may be moved vertically downward to reduce gap 360, thereby increasing the pressure within confined chamber region 304 (FIG. 3C). Conversely, to increase the conductance rate, confinement ring 302 may be moved vertically upward to increase gap 360, thereby decreasing the pressure within confined chamber region 304 (FIG. 3D).

In an embodiment, a sensor 326 may be employed to collect pressure data within confined chamber region 304. The pressure data may be sent to a precision vertical movement arrangement 324 (such as a stepper assembly, a CAM ring arrangement, etc.) for analysis. If the pressure level has traversed a predefined threshold range, the set of plungers 322 may be moved to adjust confinement ring 302 to a new position. Similar to FIG. 2, in an embodiment, at least one of the collection of data, the analysis of data, and the adjustment of set of plungers 322 may be performed automatically without human intervention.

In an embodiment, confinement ring 302 may include one or more slots 350. The set of slots (n) may provide additional paths for exhausting gas from the confined chamber region, in an embodiment. The slots may be equal in length or may have different lengths. The slots may be equally or unequally spaced. The length and cross-sectional area of the slots may also vary. In one embodiment, the set of slots may include a path to facilitate detection of plasma condition by an optical sensor, which may be employed to capture end point data during substrate processing.

In an embodiment, confinement ring 302 may be employed to manage plasma confinement while an external component may be employed to perform pressure control. Consider the situation wherein, for example, a recipe requires all components within a processing chamber to be stationary during the execution of the recipe. In this type of environment, confinement ring 302 may be positioned at a predetermined stationary position. The predetermined stationary position may be at a position that minimizes the possibility of plasma unconfinement. In an embodiment a valve such as a vat valve 352 may be employed to adjust the pressure level within confined chamber region 304.

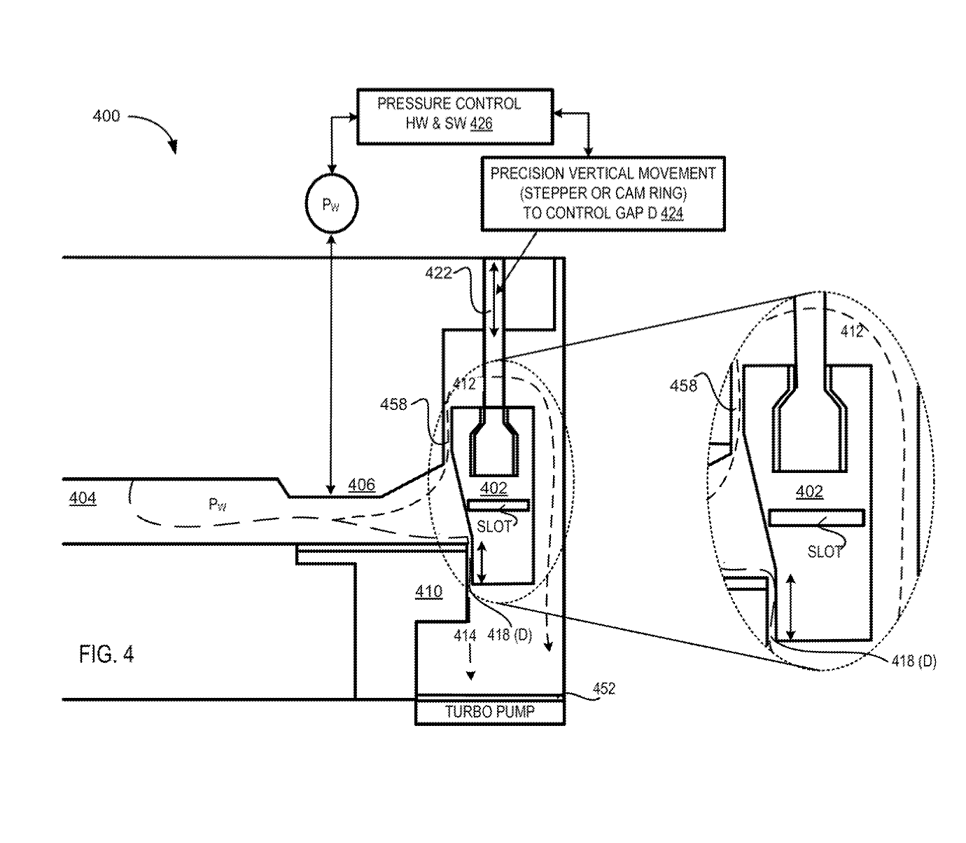

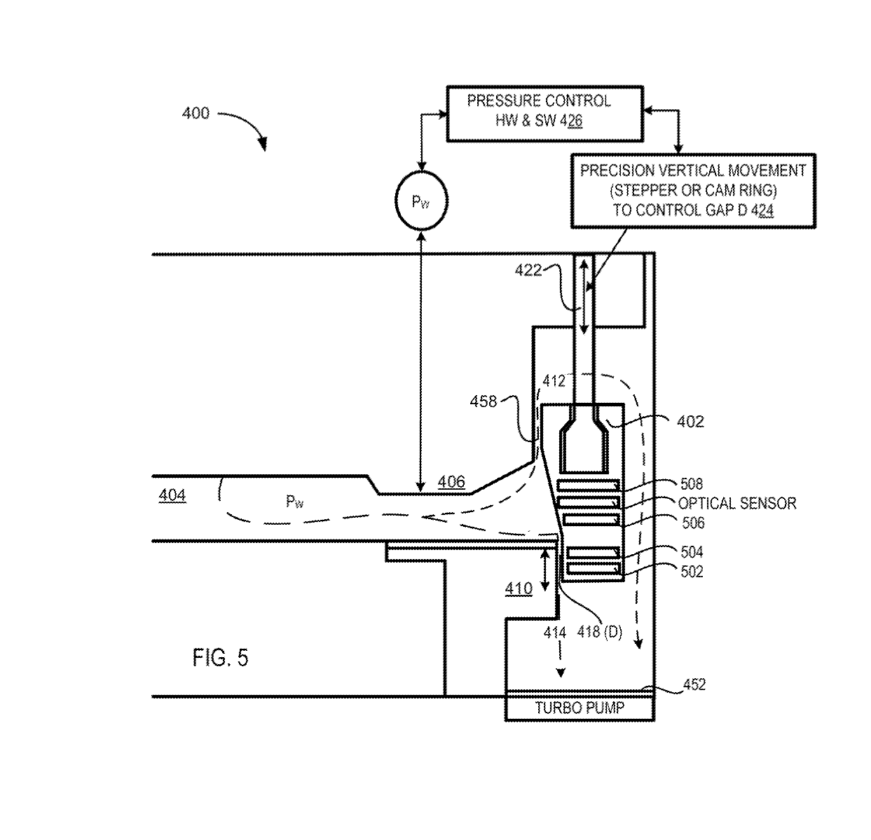

As aforementioned, conductance rate is affected by not only the cross-sectional dimension of the path but also by the length and spacing of the path. FIG. 4 and FIG. 5 are examples of how a unitized confinement ring arrangement may be employed to change the length of the path to perform plasma confinement and pressure control.

FIG. 4 shows, in an embodiment of the invention, a cross-sectional view of a unitized confinement ring arrangement within a processing chamber 400 of a plasma processing system. In an embodiment, the plasma processing system is a capacitively-coupled plasma (CCP) processing system. Consider the situation wherein, for example, a substrate is being processed within processing chamber 400. During substrate processing, plasma is formed above the substrate to perform etching.

A confinement ring 402 is employed to surround the plasma generating region (i.e., confined chamber region 404), in an embodiment, in order to confine the plasma. Similar to FIG. 2, confinement ring 402 is a single unitized confinement ring. However, confinement ring 402 may extend from an upper electrode 406 downward past the top surface of a bottom ground extension 410.

Unlike FIG. 2, both gap 458 (distance between left side wall of confinement ring 402 and right side wall of upper electrode 406 in FIG. 4) and gap 418 (distance between left side wall of confinement ring 402 and right side wall of bottom ground extension 410 in FIG. 4) may be at a fixed distance. To control the conductance rate of gas exhaust, the length of each of the paths (412 and 414) may be adjusted.

In an embodiment, the exhausted gas may be evacuated from confined chamber region 404 by moving confinement 402 vertically (up/down). As can be seen from Equation 1 above, as the length of the path (L) increases, the rate of conductance decreases. In other words, as the path lengthens, the resistance in the gas flow is increased. As a result, less gas may be exhausted from the plasma generating region and the pressure within confined chamber region 404 may increase.

As can be appreciated from the foregoing, paths 412 and 414 may have countering affect on one another. In an example, as confinement ring 402 is moved vertically downward, the portion of path 414 lengthens between unitized confinement ring 402 and bottom ground extension 410 while the portion of path 412 between unitized confinement ring 402 and upper electrode 406 has shortened. As a result, the conductance rate for lower path 414 increases while the conductance rate for upper path 412 decreases. Thus, in determining the overall conductance rate for confined chamber region 404, the conductance rates through both paths may be considered.

In an embodiment, the configuration of confinement ring 402 may minimize the possibility of variability in the conductance rate in the upper path (412). In an example, the configuration of confinement ring 402 may be such that as confinement ring 402 is moved downward, the length between the left side of confinement ring 402 and the right side of upper electrode 406 remains the same, thereby keeping the conductance rate in the upper path (412) to be relatively unchanged. In this type of configuration, the overall rate of conductance may be controlled by adjusting lower path 414.

In an embodiment, confinement ring 402 may be attached to a set of plungers 422 at the available attachment points. Again, the number of plungers depends upon the number of attachment points. The set of plungers may be moved concurrently to adjust the vertical portion of confinement ring 402. Similar to FIG. 2, a precision vertical movement arrangement 424 (such as a stepper assembly, a CAM ring arrangement, etc.) may be employed to control the movement of set of plungers 422.

In an embodiment, a feedback arrangement may be provided. The feedback arrangement may include a sensor 426 that may be employed to collect data about the pressure level within confined chamber region 404. The pressure data may be sent to precision vertical movement arrangement 424 for analysis. If the processing data traverses a threshold range, set of plungers 422 may be moved vertically in order to change the pressure level within confined chamber region 404. In an embodiment, at least one of the collection of data, the analysis of data and the adjustment of set of plungers 422 may be performed automatically without human intervention.

In an embodiment, confinement ring 402 may be employed to manage plasma confinement while an external component may be employed to perform pressure control. Consider the situation wherein, for example, a recipe requires all components within a processing chamber to be stationary during the execution of the recipe. In this type of environment, confinement ring 402 may be positioned at a predetermined stationary position. The predetermined stationary position may be at a position that minimizes the possibility of plasma unconfinement. In an embodiment a valve such as a vat valve 452 may be employed to adjust the pressure level within confined chamber region 404.

In an embodiment, confinement ring 402 may additionally or alternatively be implemented with a set of slots, as shown in FIG. 5. As aforementioned, besides size and length of the paths for exhausting gas from a confined chamber region, the number of paths (n) and spacing available for exhausting may also be a factor in the conductance rate. In an example, confinement ring 402 may have four slots (502, 504, 506, and 508). Thus, instead of only two paths (412 and 414) being available for exhausting gas from confined chamber region 404, additional four paths are available for evacuating the exhaust gas.

In an embodiment, the conductance rate of gas exhaust may also be controlled by adjusting the number of slots available. In an example, to reduce the conductance rate, one or more of the slots may be blocked to prevent the gas from exiting confined chamber region 404 through the paths provided by the slots. In an example, slots 502 and 504 are positioned below the top surface of bottom ground extension 410. Thus, only slots 506 and 508 are available to exhaust the gas from confined chamber region 404. In other words, as confinement ring 402 is moved vertically down, slots 502 and 504 may be blocked by bottom ground extension 410. As a result, the paths through slots 502 and 504 may no longer be available for evacuating the exhaust gas from confined chamber region 404.

FIGS. 2-5 have been discussed in relation to Equation 1. However, those skilled in the art are aware that Equation 1 is but one example of an equation for calculating the rate of conductance. Equation 1 has been utilized as an example to show the relationship between three variables (D, L, and n) that may affect the rate of conductance. Other equations may be also employed to calculate the rate of conductance. In an example, Equation 2 below shows an example of another equation that may be employed to calculate the rate of conductance.

$$C = \frac{2 * K * {w}^{2} * {h}^{2} * \overline{v}}{3 ( w + h ) * t} , \overline{v} = \sqrt{\frac{8 kT}{π m}} \qquad [ Equation 2 ]$$

Again, C=rate of conductance; K=constant; w=width; h=height; v=velocity; t=thickness; T=temperature; and m=mass of gas

As can be appreciated from the forgoing, one or more embodiments of the present invention provide for a unitized confinement ring arrangement. With a unitized confinement ring, the conductance rate may be managed by varying the number of paths, the size of the paths, and/or the length of the paths available, and the like. By simplifying the design, fewer mechanical components are required to perform the function of plasma confinement and/or pressure control within the plasma generating region. Since there are fewer mechanical components, the unitized confinement ring arrangement is more reliable and the cost of maintaining and servicing the unitized confinement ring arrangement is less expensive.

While this invention has been described in terms of several preferred embodiments, there are alterations, permutations, and equivalents, which fall within the scope of this invention. Although various examples are provided herein, it is intended that these examples be illustrative and not limiting with respect to the invention.

Also, the title and summary are provided herein for convenience and should not be used to construe the scope of the claims herein. Further, the abstract is written in a highly abbreviated form and is provided herein for convenience and thus should not be employed to construe or limit the overall invention, which is expressed in the claims. If the term “set” is employed herein, such term is intended to have its commonly understood mathematical meaning to cover zero, one, or more than one member. It should also be noted that there are many alternative ways of implementing the methods and apparatuses of the present invention. It is therefore intended that the following appended claims be interpreted as including all such alterations, permutations, and equivalents as fall within the true spirit and scope of the present invention.

What is claimed is:

1. An arrangement for performing pressure control in a processing chamber of a plasma processing system during processing of a substrate, said arrangement comprising:
an upper electrode;
a lower electrode;
a unitized confinement ring arrangement comprised of a single ring including slots; and
at least one plunger configured for moving the unitized confinement ring arrangement in a vertical direction to adjust at least one of a first gas conductance path and a second gas conductance path to perform the pressure control,
wherein said upper electrode, said lower electrode and said unitized confinement ring arrangement are configured at least for surrounding a confined chamber region, wherein said confined chamber region is capable of supporting a plasma for etching said substrate during substrate processing and said unitized confinement ring arrangement is configured for confining said plasma within said confined chamber region,
wherein said first gas conductance path is formed between a first protrusion of said upper electrode and a second protrusion of said unitized confinement ring arrangement, at least a portion of said second protrusion overlaps said first protrusion, said pressure control within said confined chamber region is provided by moving said at least one plunger vertically to adjust the length of said first gas conductance path, said second gas conductance path is formed between a bottom surface of said unitized confinement ring arrangement and a top surface of said lower electrode, at least a portion of the width of said bottom surface of said unitized confinement ring arrangement overlaps said top surface of said lower electrode, and said pressure control within said confined chamber region is provided by moving said at least one plunger vertically to adjust the width of said second gas conductance path.

2. The arrangement of claim 1 wherein said unitized confinement ring arrangement is made from a dielectric material.

3. The arrangement of claim 1 wherein said unitized confinement ring arrangement is made from a conductive material.

4. The arrangement of claim 1 wherein said plasma processing system is a capactively-coupled plasma processing system.

5. The arrangement of claim 1 further including an automatic feedback arrangement configured at least for monitoring and stabilizing the pressure within said confined chamber region.

6. The arrangement of claim 5 wherein said automatic feedback arrangement includes a set of sensors configured for collecting processing data about pressure volume within said confined chamber region.

7. The arrangement of claim 6 wherein said automatic feedback arrangement includes a precision vertical movement arrangement configured at least for
receiving said processing data from said set of sensors,
analyzing said processing data, and
determining a new position for said unitized confinement ring arrangement.

8. The arrangement of claim 1 wherein said slots are a set of slots, wherein each slot of said set of slots is configured for providing an additional path for exhausting gas from said confined chamber region, wherein the availability of said each slot is adjusted by moving said at least one plunger vertically.

9. An arrangement for performing pressure control in a processing chamber of a plasma processing system during processing of a substrate, said arrangement comprising:
an upper electrode;
a lower electrode;
a unitized confinement ring arrangement comprised of a single ring including slots, wherein said upper electrode, said lower electrode and said unitized confinement ring arrangement are configured at least for surrounding a confined chamber region, wherein said confined chamber region is capable of supporting a plasma for etching said substrate during substrate processing and said unitized confinement ring arrangement is configured for confining said plasma within said confined chamber region;
a valve configured at least for controlling pressure within said confined chamber region; and
at least one plunger configured for moving the unitized confinement ring arrangement in a vertical direction to adjust at least one of a first gas conductance path and a second gas conductance path to perform the pressure control,
wherein said first gas conductance path is formed between a first protrusion of said upper electrode and a second protrusion of said unitized confinement ring arrangement, at least a portion of said second protrusion overlaps said first protrusion, said pressure control within said confined chamber region is provided by moving said at least one plunger vertically to adjust the length of said first gas conductance path, said second gas conductance path is formed between said lower electrode and said unitized confinement ring arrangement, and said pressure control within said confined chamber region is provided by moving said at least one plunger vertically to adjust the width of said second gas conductance path.

10. The arrangement of claim 9 wherein said first gas conductance path provides a first route for exhausting gas from said confined chamber region.

11. The arrangement of claim 10 wherein said second gas conductance path provides a second route for exhausting said gas from said confined chamber region.

12. The arrangement of claim 9 further including an automatic feedback arrangement configured at least for monitoring and stabilizing the pressure within said confined chamber region.

13. The arrangement of claim 9 wherein said unitized confinement ring arrangement is made from at least one of a dielectric material and a conductive m 1.
